(19) United States
(12) Patent Application Publication
(10) Pub. No.: US 2012/0326579 A1
(43) Pub. Date: Dec. 27, 2012

(54) COMPUTER ENCLOSURE WITH PULL TAB

(75) Inventors: CHEN-RUEI TU, Tu-Cheng (TW); LI-PING CHEN, Tu-Cheng (TW)

(73) Assignee: HON HAI PRECISION INDUSTRY CO., LTD., Tu-Cheng (TW)

(21) Appl. No.: 13/237,322

(22) Filed: Sep. 20, 2011

(30) Foreign Application Priority Data
Jun. 21, 2011 (TW) 100121540

(51) Int. Cl. H05K 5/02

(52) U.S. Cl. 312/223.2

(57) ABSTRACT

A computer enclosure includes a chassis, a mounting bracket, and a pull tab. The mounting bracket is mounted to the chassis. The mounting bracket includes a resilient clip. A fastener is located on the resilient clip. The pull tab is located between the chassis and the mounting bracket. The pull tab is engaged with the mounting bracket. A channel is defined in the pull tab and extends along a first direction. The fastener extends through the channel, and the pull tab is removable along the first direction with the fastener guided by the channel.

### BACKGROUND

1. Technical Field

The present disclosure relates to computer enclosures, especially to a computer enclosure with a pull tab.

2. Description of Related Art

Many computers have an information label about the computer on the enclosure. The information label is sometimes located on a pull tab, which can be slid from the enclosure of the computer when one wants to read the information about the computer. The pull tab is directly retained in a sliding way of a bracket mounted to the enclosure. However, the present pull tabs cannot be smoothly guided by the sliding way of the bracket. Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a computer enclosure according to one embodiment.

FIG. 2 is an assembled view of the computer enclosure of FIG. 1.

FIG. 3 is a cross sectional view taken along line III-III of FIG. 2.

FIG. 4 is similar to FIG. 3, but a pull tab is moved away from a chassis.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

An embodiment of a computer enclosure can be a server rack enclosure for receiving servers or an enclosure for receiving computer hardware directly.

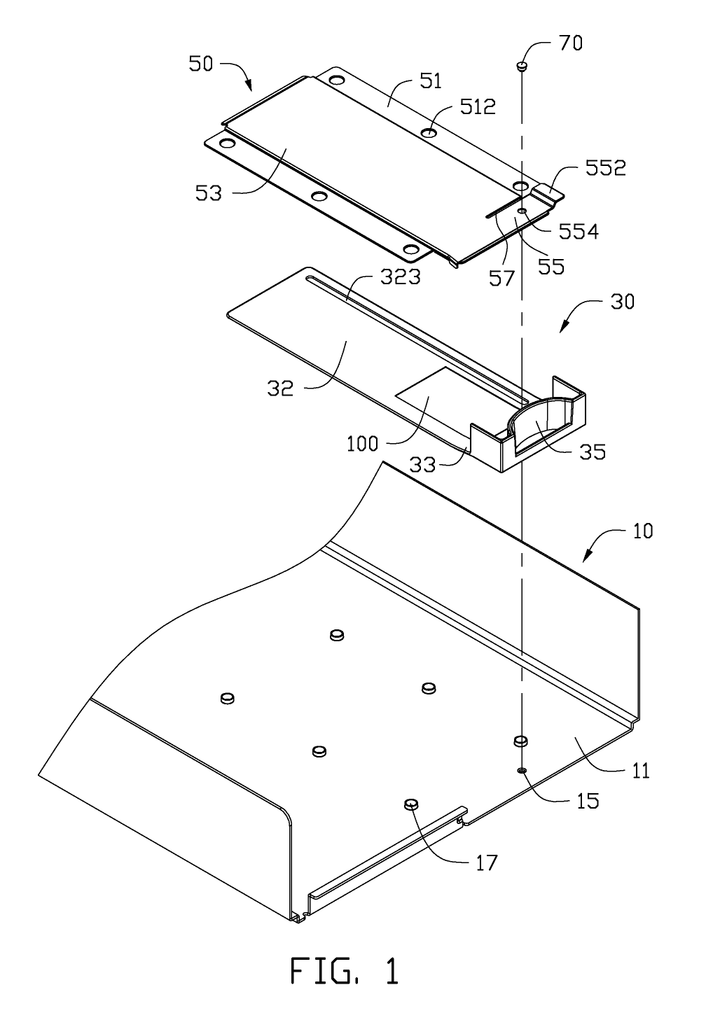

Referring to FIG. 1, the computer enclosure includes a chassis 10, a pull tab 30, and a mounting bracket 50.

The chassis 10 includes a bottom wall 11. A plurality of hollow collar posts 17 is located on the bottom wall 11. A mounting hole 15 is defined in the bottom wall 11.

The mounting bracket 50 includes a top board 53, two side flanges 51 and a resilient clip 55. The two side flanges 51 extend from opposite sides of the top board 53. The two side flanges 51 are located at a lower plane relative to a plane of the top board 53. A plurality of mounting holes 512 is defined in each of the side flanges 51 corresponding to the collar posts 17. The resilient clip 55 is deformable relative to the top board 53. A slot 57 is defined between the resilient clip 55 and the top board 53. The slot 57 traverses the top board 53 and extends to a middle line of the top board 53. A locking hole 554 is defined in the resilient clip 55. An operation finger 552 is located at a distal end of the resilient clip 55 for pulling the resilient clip 55.

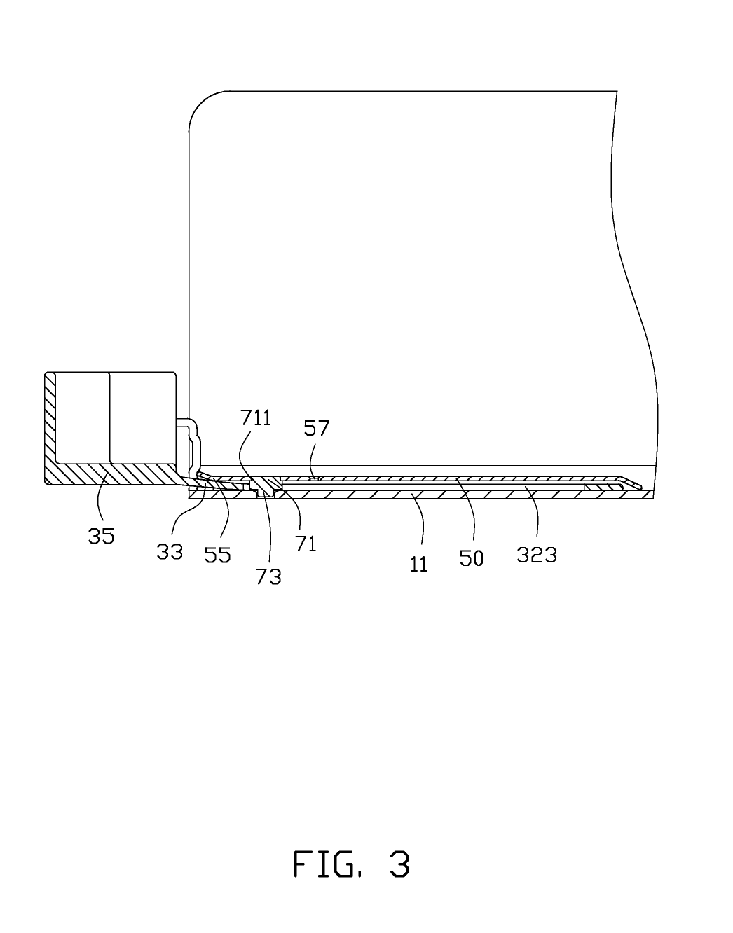

A fastener 70 extends through the locking hole 554 and engages with the resilient clip 55. The fastener 70 includes a body 71 and a foot 73. The body 71 can be deformed and is engaged in the locking hole 554. An annular groove 711 is defined around the body 71 to engage with the resilient clip 55 (see FIG. 3). The foot 73 protrudes downward from the resilient clip 55.

The pull tab 30 may be used to attach an information label 100 about a computer. The pull tab 30 includes a rectangular supporting board 32, a holding board 33, and a handle 35. A channel 323, or a through slot, is defined in the supporting board 32 along a first direction. The channel 323 travels along a straight line in one embodiment. The resilient holding board 33 is oblique to the supporting board 32. The resilient holding board 33 may be curved. The handle 35 extends from the resilient holding board 33. An arcuate holding space is defined in the handle 35 for facilitating being pulled by hand.

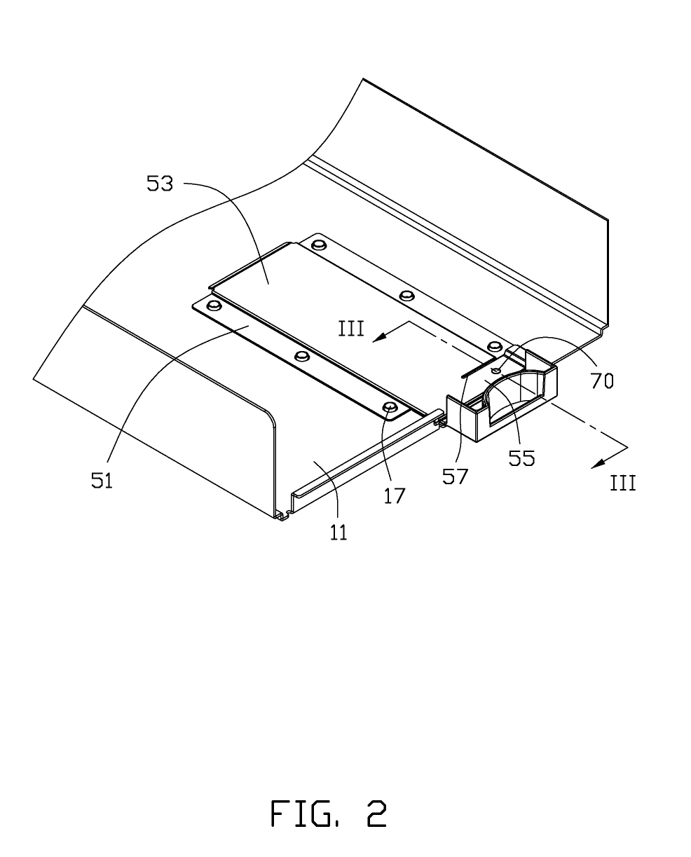

Referring to FIG. 2 and FIG. 3, when the mounting bracket 50 is mounted to the chassis 10, the mounting bracket 50 is located on the bottom wall 11 with the collar posts 17 extending through the corresponding mounting holes 512 of the mounting bracket 50. The collar post 17 can be riveted to retain the mounting bracket 50 to the chassis 10. A receiving space is defined between the top board 53 and the bottom wall 11.

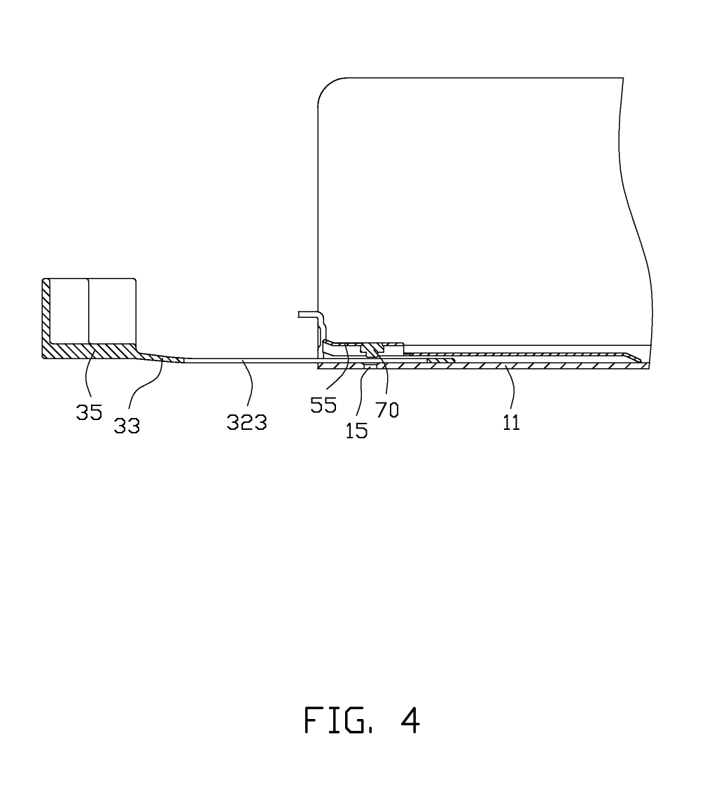

Referring to FIG. 4, when the pull tab 30 is installed on the chassis 10, the resilient clip 55 is deformed upward. The pull tab 30 is moved into the receiving space of from an side of the chassis 10. The resilient clip 55 is released and rebounds back to an original state. In the original state, the resilient clip 55 is substantially parallel to a plane of the top board 53, and the fastener 70 extends through the channel 323 and the mounting hole 15. The pull tab 30 may be guided by the channel 323.

Referring to FIG. 3, when the pull tab 30 is moved into the receiving space, the holding board 33 is deformed by the mounting bracket 50. The pull tab 53 is retained by the mounted bracket 50. The pull tab 30 is partially located in the receiving space with handle 35 exposed outside the chassis 10.

Referring to FIG. 4, when one wants to see the information label 100, the pull tab 53 is pulled from the chassis 10, and the holding board 33 is released and rebounds to the original state. The pull tab 53 can be restricted in the channel 323 from being detached from the chassis.

It is also to be understood, however, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the disclosure to the full extent indicated by the broad general meaning of the terms in which the appended claims are expressed.

1. A computer enclosure comprising:
a chassis;
a mounting bracket mounted to the chassis, the mounting bracket comprising a resilient clip, a fastener located on the resilient clip; and
a pull tab located between the chassis and the mounting bracket, the pull tab comprising a supporting board, a resilient holding board extending from the supporting board, and a channel in the pull tab and extending along a first direction, the supporting board being substantially parallel to the resilient clip in an original state, the resilient holding board being engaged with the resilient clip of the mounting bracket;
wherein the fastener extends through the channel, and the pull tab is removable along the first direction with the fastener guided by the channel.

2. The computer enclosure of claim 1, wherein the channel extends along a straight line.

3. The computer enclosure of claim 2, wherein the mounting bracket further comprises a top board, a receiving space is defined between the top board and the chassis, and the pull tab is partially located in the receiving space.

4. The computer enclosure of claim 3, wherein a slot is defined between the top board and the resilient clip, the slot travels along a second direction substantially perpendicular to the first direction, and the resilient clip is substantially parallel to a plane of the top board.

5. The computer enclosure of claim 1, wherein an annular groove is defined around the fastener to engage with the resilient clip.

6. The computer enclosure of claim 1, wherein the fastener comprises a body, a locking hole is defined in the resilient clip, and the body is deformably engaged in the locking hole.

7. The computer enclosure of claim 1, wherein the fastener comprises a foot, and a mounting hole is defined in the chassis for receiving the foot.

8. The computer enclosure of claim 1, wherein the resilient holding board is oblique to the supporting board, and the resilient holding board is deformable by the supporting board.

9. The computer enclosure of claim 8, wherein the pull tab further comprises a handle connected to the resilient holding board, and the handle is located at a side of the mounting bracket.

10. (canceled)

11. A computer enclosure comprising:
a chassis;
a mounting bracket mounted to the chassis, the mounting bracket comprising a resilient clip, a fastener located on the resilient clip; and
a pull tab located between the chassis and the mounting bracket, the pull tab engaged with the mounting bracket, and a channel defined in the pull tab and extending along a first direction;
wherein the resilient clip is rotatable from a first state where the fastener extends through the channel and the pull tab is removable along the first direction with the fastener guided by the channel, to a second state where the resilient clip is deformed and the fastener is disengaged from the channel.

12. The computer enclosure of claim 11, wherein the channel extends along a straight line.

13. The computer enclosure of claim 12, wherein the mounting bracket further comprises a top board, a receiving space is defined between the top board and the chassis, and the pull tab is partially located in the receiving space.

14. The computer enclosure of claim 13, wherein a slot is defined between the top board and the resilient clip, the slot travels along a second direction substantially perpendicular to the first direction, and the resilient clip is substantially parallel to a plane of the top board at the first state.

15. The computer enclosure of claim 11, wherein an annular groove is defined around the fastener to engage with the resilient clip.

16. The computer enclosure of claim 11, wherein the fastener comprises a body, a locking hole is defined in the resilient clip, and the body is deformably engaged in the locking hole.

17. The computer enclosure of claim 11, wherein the fastener comprises a foot, and a mounting hole is defined in the chassis for receiving the foot.

18. The computer enclosure of claim 11, wherein the supporting board being substantially parallel to the resilient clip in the first state, the pull tab comprises a supporting board and a resilient holding board oblique to the supporting board, and the resilient holding board is deformable and is engaged with the resilient clip.

19. The computer enclosure of claim 18, wherein the pull tab further comprises a handle connected to the resilient holding board, and the handle is located at a side of the mounting bracket.

20. (canceled)

21. The computer enclosure of claim 4, wherein the slot substantially extends to a middle portion of the top board.

22. The computer enclosure of claim 14, wherein the slot substantially extends to a middle portion of the top board.
